(19) United States
(12) Patent Application Publication
(10) Pub. No.: US 2021/0408075 A1
(43) Pub. Date: Dec. 30, 2021

(54) DISPLAY PANEL AND MANUFACTURING METHOD THEREOF

(71) Applicant: WUHANCHINA STAR OPTOELECTRONICS SEMICONDUCTOR DISPLAY TECHNOLOGY CO., LTD., Wuhan (CN)

(72) Inventor: Zhiwei ZHOU, Wuhan (CN)

(73) Assignee: WUHANCHINA STAR OPTOELECTRONICS SEMICONDUCTOR DISPLAY TECHNOLOGY CO., LTD., Wuhan (CN)

(21) Appl. No.: 16/652,999

(22) PCT Filed: Nov. 18, 2019
(86) PCT No.: PCT/CN2019/119286

§ 371 Date: Apr. 2, 2020

(30) Foreign Application Priority Data
Oct. 24, 2019 (CN) 201911017025.1

(51) Int. Cl. H01L 27/12

(52) U.S. Cl. CPC H01L 27/1244; H01L 29/45; H01L 27/1259

(57) ABSTRACT

A display panel and a manufacturing method thereof are provided. By using advantages of conductive polymers, such as their ability to form large-area films and conduciveness to performing patterning, and having an electrical conductivity comparable with metals, good bending resistance, conductivity that does not decrease with increasing temperature, strong conductance direction, etc. A conductive polymer material is used to replace a metal material of wirings in the display panel to simultaneously satisfy requirements of electrical conduction and good bending resistance.

### CROSS REFERENCE TO RELATED APPLICATIONS

The present disclosure claims the priority of Chinese Patent Application No. CN201911017025.1 filed on Oct. 24, 2019 with the National Intellectual Property Administration, titled “DISPLAY PANEL AND MANUFACTURING METHOD THEREOF”, which is incorporated by reference in the present application in its entirety.

### FIELD OF INVENTION

The present disclosure relates to the field of display technology, and specifically relates to a display panel and a manufacturing method thereof.

### BACKGROUND OF INVENTION

Organic light emitting diode (OLED) devices are also known as organic electroluminesence display devices, or organic light emitting semiconductors. A basic structure of OLEDs is indium tin oxide (ITO), which is thin and transparent and has characteristics of semiconductors, connected to a positive electrode/anode of electricity, and it is added another cathode with a metal surface. Then, they are packaged into a sandwich-like structure. An entire structural layer includes a hole transport layer (HTL), a light emitting layer (EL) and an electron transport layer (ETL). When an electric power is supplied to an appropriate voltage, electron holes of the positive electrode and electrons of the surface cathode are combined in the light emitting layer, and under Coulomb force, excitons (electron-hole pairs) in an excited state are combined at a certain probability, and the excited state is unstable in a general environment. The excitons in the excited state recombine and transfer energy to a luminescent material, causing it to jump from a ground state to the excited state, and energy in the excited state generates photons through a radiation relaxation process to release light energy and produce light. Furthermore, according to different formulas of the luminescent material, it can produce three primary colors of red, green, and blue, RGB, to form basic colors.

First, OLEDs have self-illuminating characteristics, and they are unlike thin film transistor liquid crystal displays (TFT-LCDs), which require backlights, so visibility and brightness of OLEDs are high. Second, OLEDs have advantages such as low voltage demand, high power saving efficiency, quick response times, light weight, thinness, simple structure, low cost, wide viewing angles, almost infinitely high contrast, low power consumption, high reaction speed, etc., and they have become one of the most important display technologies today and are gradually replacing TFT-LCDs. They are expected to become the next generation mainstream display technology after LCDs.

As major panel manufacturers are continuously increasing development of flexible displays, electronic products with multi-fold functions seem to be on the horizon. Actually, development of display screens with foldable functions represented by organic light emitting diode (OLED) displays has encountered many technical obstacles. One of the main difficulties is that each film layer of the OLED displays not only needs to meet requirements of excellent bending resistance without cracks, but also needs to ensure good electrical conductivity (metal wirings), insulation performance (inorganic film layers), and water/oxygen barrier property (inorganic film layers). However, metal wirings used in current OLED displays mainly include Mo, Ti, and Al with high elastic modulus. Although metals have greater bending resistance than inorganic film layers, with continuous reduction of bending radii and continuous increase of product bending times, it is becoming more difficult for metal materials used currently to satisfy increasingly harsher requirements. Hence, under conditions of the prior art, cracks easily occur on the metal wirings after bending. Therefore, it is necessary to seek a new type of material to replace materials of the metal wirings and to satisfy usage requirements of electric conduction and resistance to extreme bending.

### SUMMARY OF INVENTION

One purpose of the present disclosure is to provide a display panel and a manufacturing method thereof, which can replace the material of the metal routes and can satisfy using requirements of electric conduction and ultra bending resistance.

In order to solve the problems mentioned above, one embodiment of the present disclosure provides a display panel, which includes a substrate layer and a conductive layer. Furthermore, the conductive layer is disposed on the substrate layer, and the conductive layer is a conductive polymer thin film.

Furthermore, the conductive polymer thin film includes one of a conductive polypyrrole thin film, a conductive polyaniline thin film, a conductive polythiophene thin film, or a heterocyclic conductive polymer thin film.

Furthermore, the conductive layer includes one or more of a gate electrode layer and a source/drain electrode layer.

Furthermore, the display panel further includes an active layer, a gate insulating layer, and an interlayer insulation layer. The active layer is disposed on the substrate layer. The gate insulating layer is disposed on the active layer. The gate electrode layer is disposed on the gate insulating layer. The interlayer insulation layer is disposed on the gate electrode layer. A source/drain electrode layer is disposed on the interlayer insulation layer. The source/drain electrode layer is connected to the active layer through a via hole.

Another embodiment of the present disclosure provides a manufacturing method of the display panel related to the present disclosure, which includes steps as follows: step S1 manufacturing a substrate layer; and step S2 coating a basic polymer solution on the substrate layer to form a basic polymer thin film, then performing a drying process on the basic polymer thin film to form the conductive polymer thin film, and finally forming the conductive layer.

Furthermore, the basic polymer solution in the step S2 includes one of a basic polypyrrole solution, a basic polyaniline solution, a basic polythiophene solution, or a heterocyclic polymer solution.

Furthermore, the basic polyaniline solution in the step S2 is prepared and formed by adding an oxidant into a hydrochloric acid solution to perform an oxidative polymerization of aniline monomers to obtain conductive polyaniline powders doped with hydrochloric acid, and then making the conductive polyaniline powders doped with the hydrochloric acid be dedoped by ammonia water to obtain basic polyaniline powders, and by dissolving the basic polyaniline powders in a first solution.

Furthermore, the oxidant includes one of FeCl₃ or (NH₄)₂S₂O₈.

Furthermore, the first solution is N-methyl pyrrolidone.

Furthermore, a wet etching process is performed on the conductive polymer thin film in the step S2 to obtain one or more of a patterned gate electrode layer and a patterned source/drain electrode layer.

The present disclosure relates to a display panel and a manufacturing method thereof. The present disclosure uses advantages of conductive polymers, such as their ability to form large-area films and conduciveness to performing patterning, and having an electrical conductivity comparable with metals, good bending resistance, conductivity that does not decrease with increasing temperature, strong conductance direction, etc. A conductive polymer material is used to replace a metal material of wirings in the display panel to simultaneously satisfy requirements of electrical conduction and good bending resistance.

### DESCRIPTION OF DRAWINGS

To more clearly illustrate the technical solutions of the embodiments of the present disclosure, the accompanying figures of the present disclosure will be described in brief. Obviously, the accompanying figures described below are only part of the embodiments of the present disclosure, from which those skilled in the art can derive further figures without making any inventive efforts.

FIG. 1 is a structural schematic diagram of a display panel of the present disclosure.

FIG. 2 is a manufacturing flowchart of the display panel of the present disclosure.

### DETAILED DESCRIPTION OF PREFERRED EMBODIMENTS

The preferred embodiments of the present disclosure are described in detail below with reference to the accompanying figures to completely introduce technical content of the present disclosure to those skilled in the art, and to give an example that the present disclosure can be implemented. This makes the technical content of the present disclosure clearer and those skilled in the art will more readily understand how to implement the present disclosure. However, the present disclosure can be implemented in many different forms of embodiments. The scope of the present disclosure is not limited to the embodiments mentioned herein, and the description of the embodiments below is not intended to limit the scope of the present disclosure.

The directional terms of which the present disclosure mentions, for example, “top”, “bottom”, “upper”, “lower”, “front”, “rear”, “left”, “right”, “inside”, “outside”, “side”, etc., just refer to directions of the accompanying figures. The directional terms used herein are used to explain and describe the present disclosure, and are not intended to limit the scope of the present disclosure.

In the figures, components with similar structures are indicated by the same reference numerals, and components that have similar structure or function are indicated by the similar reference numerals. Moreover, for ease of understanding and description, the dimensions and thickness of each component shown in the accompanying figures are arbitrarily shown, and the present disclosure does not limit the dimensions and thickness of each component.

When a component is described as “on” another component, the component can be placed directly on the other component; there can also be an intermediate component, the component is placed on the intermediate component, and the intermediate component is placed on another component. When a component is described as “mounted” or “connected to” another component, it can be understood as “directly mounted” or “directly connected to”, or a component is “mounted” or “connected to” through an intermediate component to another component.

### First Embodiment

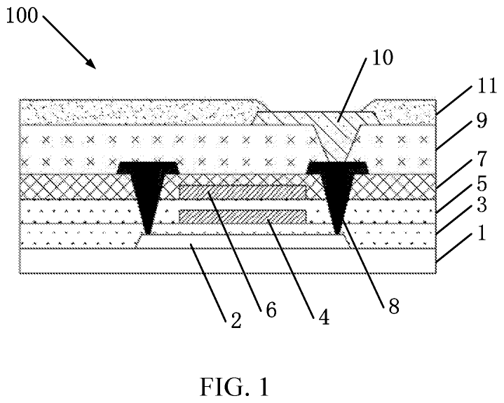

As illustrated in FIG. 1, a display panel 100 includes a substrate layer 1 and a conductive layer. The conductive layer is a conductive polymer thin film. The conductive layer can be one or more of a first gate electrode layer 4, a second gate electrode layer 6, and source/drain electrode layer 8.

The display panel 100 further includes an active layer 2, a first gate insulating layer 3, a second gate insulating layer 5, an interlayer insulation layer 7, a planarization layer 9, anodes 10, and a pixel definition layer 11. Furthermore, the active layer 2 is disposed on the substrate layer 1. The gate insulating layer 3 is disposed on the active layer 2. The first gate electrode layer 4 is disposed on the first gate insulating layer 3. The second gate insulating layer 5 is disposed on the first gate electrode layer 4. The second gate electrode layer 6 is disposed on the second gate insulating layer 5. The interlayer insulation layer 7 is disposed on the second gate electrode layer 6. The source/drain electrode layer 8 is disposed on the interlayer insulation layer 7. The source/drain electrode layer 8 is connected the active layer 2 through a first via hole. The planarization layer 9 is disposed on the source/drain electrode layer 8. The anodes 10 are spaced apart on the planarization layer 9. The anodes 10 are connected to the source/drain electrode layer 8 through a second via hole. The pixel definition layer 11 is disposed on the planarization layer 9 between adjacent anodes 10. Furthermore, at least one of the first gate electrode layer 4, the second gate electrode layer 6, or the source/drain electrode layer 8 is the conductive polymer thin film.

Furthermore, the conductive polymer film includes one of a conductive polypyrrole thin film, a conductive polyaniline thin film, a conductive polythiophene thin film, or a heterocyclic conductive polymer thin film. The first gate electrode layer 4, the second gate electrode layer 6, and the source/drain electrode layer 8 manufactured by the conductive polymer thin film have electrical conductivity and good bending resistance, which prevents occurrences of phenomena such as fragmentation, bright lines, dark lines, etc. after the display panel 100 is bent, thereby improving service life of the display panel 100 and reducing production cost.

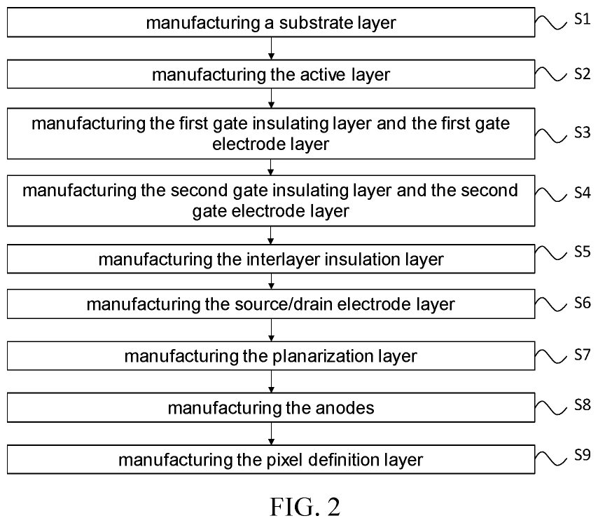

As illustrated in FIG. 2, the present disclosure further provides a manufacturing method for manufacturing the display panel 100 of the present disclosure, which includes steps as follows: step S1, manufacturing the substrate layer 1; step S2, manufacturing the active layer 2 on the substrate layer 1; step S3, manufacturing the first gate insulating layer 3 on the active layer 2, and manufacturing the first gate electrode layer 4 on the first gate insulating layer 3; step S4, manufacturing the second gate insulating layer 5 on the first gate electrode layer 4, and manufacturing the second gate electrode layer 6 on the second gate insulating layer 5; step S5, manufacturing the interlayer insulation layer 7 on the second gate electrode layer 6; step S6, manufacturing the source/drain electrode layer 8 on the interlayer insulation layer 7, and connecting the source/drain electrode layer 8 to the active layer 2 through the first via hole; step S7, manufacturing the planarization layer 9 on the source/drain electrode layer 8; step S8, manufacturing the anodes 10 spaced apart on the planarization layer 9; and step S9, manufacturing the pixel definition layer 11 on the planarization layer 9 between the adjacent anodes 10.

Furthermore, in the step S3, coating a basic polymer solution on the first gate insulating layer 3 to form a basic polymer thin film, then performing a drying process on the basic polymer thin film to form the conductive polymer thin film, and finally forming the conductive layer 4 by a wet etching method.

Furthermore, in the step S4, coating the basic polymer solution on the second gate insulating layer 5 to form the basic polymer thin film, then performing the drying process on the basic polymer thin film to form the conductive polymer thin film, and finally obtaining the patterned second gate electrode layer 6 by the wet etching method.

Furthermore, in the step S6, coating the basic polymer solution on the interlayer insulation layer 7 to form the basic polymer thin film, then performing the drying process on the basic polymer thin film to form the conductive polymer thin film, and finally obtaining the patterned source/drain electrode layer 8 by the wet etching method.

Specifically, the basic polymer solution mentioned above includes one of a basic polypyrrole solution, a basic polyaniline solution, a basic polythiophene solution, or a heterocyclic polymer solution.

Specifically, the basic polyaniline solution is prepared and formed by adding an oxidant into a hydrochloric acid solution to perform an oxidative polymerization of aniline monomers to obtain conductive polyaniline powders doped with hydrochloric acid, and then making the conductive polyaniline powders doped with the hydrochloric acid be dedoped by ammonia water to obtain basic polyaniline powders, and by dissolving the basic polyaniline powders in a first solution.

Furthermore, the oxidant includes one of FeCl₃ or (NH₄)₂S₂O₈. Furthermore, the first solution is N-methyl pyrrolidone (NMP).

Preparing and forming the conductive layer of the display panel 100 by using the conductive polymer such as polyaniline, etc. can not only satisfy a requirement of electrical conduction, but also uses the good bending resistance of the conductive polymer to prevent occurrence of phenomena such as fragmentation, bright lines, dark lines, etc. during bending, thereby improving service life of the display panel 100 and reducing production cost.

The display panel 100 and the manufacturing method thereof provided by the present disclosure are described in detail above. It should be understood that the exemplary embodiments described herein should be considered in descriptive, and is used for understanding the method of the present disclosure and its main idea, and is not intended to limit the present disclosure. Descriptions of features or aspects in each exemplary embodiment should generally be considered as being applied to similar features or aspects in other exemplary embodiments. While the present disclosure has been described with reference to the preferred embodiments, various modifications and changes can be made by those skilled in the art. The present disclosure is intended to cover such varieties and modifications within the scope of the appended claims, and any modifications, equivalents, and improvements made within the spirit and scope of the present disclosure should be included in the scope of the present disclosure.

What is claimed is:

1. A display panel, comprising:
a substrate layer; and
a conductive layer disposed on the substrate layer;
wherein the conductive layer is a conductive polymer thin film.

2. The display panel as claimed in claim 1, wherein the conductive polymer thin film comprises one of a conductive polypyrrole thin film, a conductive polyaniline thin film, a conductive polythiophene thin film, or a heterocyclic conductive polymer thin film.

3. The display panel as claimed in claim 1, wherein the conductive layer comprises one or more of a gate electrode layer and a source/drain electrode layer.

4. The display panel as claimed in claim 3, wherein the display panel comprises:
an active layer disposed on the substrate layer;
a gate insulating layer disposed on the active layer, wherein the gate electrode layer is disposed on the gate insulating layer; an interlayer insulation layer disposed on the gate electrode layer, wherein the source/drain electrode layer is disposed on the interlayer insulation layer, and
the source/drain electrode layer is connected to the active layer by a plurality of via holes.

5. A manufacturing method of the display panel as claimed in claim 1, comprising:
step S1, manufacturing the substrate layer; and
step S2, coating a basic polymer solution on the substrate layer to form a basic polymer thin film, then performing a drying process on the basic polymer thin film to form the conductive polymer thin film, and finally forming the conductive layer.

6. The manufacturing method of the display panel as claimed in claim 5, wherein the basic polymer solution includes one of a basic polypyrrole solution, a basic polyaniline solution, a basic polythiophene solution, or a heterocyclic polymer solution.

7. The manufacturing method of the display panel as claimed in claim 6, wherein the basic polyaniline solution is prepared and formed by adding an oxidant into a hydrochloric acid solution to perform an oxidative polymerization of aniline monomers to obtain conductive polyaniline powders doped with hydrochloric acid, and then making the conductive polyaniline powders doped with the hydrochloric acid be dedoped by ammonia water to obtain basic polyaniline powders, and by dissolving the basic polyaniline powders in a first solution.

8. The manufacturing method of the display panel as claimed in claim 7, wherein the oxidant comprises one of FeCl₃ or (NH₄)₂S₂O₈.

9. The manufacturing method of the display panel as claimed in claim 7, wherein the first solution is N-methyl pyrrolidone.

10. The manufacturing method of the display panel as claimed in claim 5, wherein a wet etching process is performed on the conductive polymer thin film to obtain one or more of a patterned gate electrode layer and a patterned source/drain electrode layer.
